(19) United States
(12) Patent Application Publication
(10) Pub. No.: US 2005/0079642 A1
(43) Pub. Date: Apr. 14, 2005

(54) Manufacturing method of nitride semiconductor device

(75) Inventor: Satoshi Tamura, Ibaraki-shi (JP)

Correspondence Address: PARKHURST & WENDEL, L.L.P., 1421 PRINCE STREET, SUITE 210, ALEXANDRIA, VA, 22314-2805, US

(73) Assignee: Matsushita Elec. Ind. Co. Ltd., Kadoma-shi (JP)

(21) Appl. No.: 10/958,395

(22) Filed: Oct. 6, 2004

(30) Foreign Application Priority Data
Oct. 14, 2003 (JP) 2003-353036

(51) Int. Cl. H01L 21/00; H01L 23/48; H01L 29/40

(52) U.S. Cl. 438/22; 438/46

(57) ABSTRACT

A first nitride semiconductor layer (202) and a second nitride semiconductor layer (203) of which etching rate is slower than the first nitride semiconductor layer (202) are sequentially formed on a base material substrate (201), and after separating the base material substrate (201) by LLO, the first nitride semiconductor layer (202) is removed by etching. Since the etching rate of the second nitride semiconductor layer (203) is slower than the first nitride semiconductor layer (202), a flattened second nitride semiconductor layer surface can be acquired, and therefore a nitride semiconductor device which excels in device characteristics and can emit light uniformly can be manufactured.

### BACKGROUND OF THE INVENTION

1. Field of the Invention

The present invention relates to a manufacturing method of a nitride semiconductor device, such as a light emitting device which emits light in an area ranging from the blue region to the ultraviolet region (e.g. a light emitting diode and a semiconductor laser).

2. Description of the Related Art

Light emitting diodes using Group III nitride are widely used for various displays, large displays, traffic lights and other applications. White LEDs, where a GaN LED and a fluorescent substance are combined, have also been commercialized, and if the luminous efficiency is improved in the future, current illumination devices are expected to be replaced.

Generally, Group III nitride semiconductors are formed on a GaN compound layer grown on a sapphire substrate. A sapphire substrate, however, has no conductivity, so both p and n electrodes must be formed on one surface of a GaN growth layer. Therefore the series resistance increases, and the device size also increases. In order to solve these problems, a technology called Laser Lift-Off (hereafter LLO) was developed.

LLO is a method of irradiating a laser from the sapphire substrate side after growing a GaN layer on a sapphire substrate, and separating the sapphire substrate and the GaN layer by thermal decomposition at the area around the interface of the GaN layer with the sapphire substrate. Separating the GaN layer and the sapphire substrate by LLO, the p electrode and the n electrode are formed on the surface of the GaN layer facing the sapphire substrate respectively.

Now a conventional manufacturing method of a nitride semiconductor device will be described with reference to FIG. 6.

FIG. 6 shows cross-sectional views of the steps depicting a conventional manufacturing method of a Group III nitride semiconductor device using LLO.

In FIG. 6, a GaN layer 102 is first deposited on a sapphire substrate 101 (FIG. 6a). Then an electrode layer 103 is formed on the GaN layer 102, and then an insulation film 104 is formed partially on the electrode layer 103 (FIG. 6b). Then about a 50 μm thick Cu plating 105 is formed on the electrode layer 103, but Cu is not plated on the insulator 104, so the Cu plating 105 is formed on the electrode layer 103 in the shape shown in FIG. 6c. Then a holding metal 106 is formed on the Cu plating 105 (FIG. 6d). Then LLO is performed to separate the sapphire substrate 101. After separating the sapphire substrate 101, an electrode layer 107 is formed on the GaN layer 102, then the holding metal 106 is separated (FIG. 6e). The top and bottom of the drawings are reversed between FIG. 6d and FIG. 6e. After the holding metal 106 is separated, the GaN layer 102 is marked and cleaved to separate the chip. Since the adherence strength is relatively weak at the adhering area of the Cu plating 105, the Cu plating 105 can be easily separated when the GaN layer 102 is cleaved (FIG. 6f) (e.g. Japanese Patent Application Laid-Open No. 2001-274507).

Here, according to the LLO technology, the GaN layer is melted by heat and separated from the sapphire substrate, therefore large bumps are generated on the exposed GaN layer 102. The size of the bumps formed is about 20 nm based on experiment, however this depends on the LLO conditions and the GaN growth layer structure.

To fabricate a surface emitting laser, it is necessary to create a high reflection mirror, which has a low irregular reflection and a low loss of light, in both the emitting end and the rear end.

To fabricate a light emitting diode, the GaN layer 102 generally becomes a light emitting surface, so if large bumps exist on the GaN layer 102, uniform light emission becomes difficult.

In a general manufacturing step of semiconductor devices, no etching technology was used for flattening to a degree required for the light emitting surface of the light emitting diode and semiconductor laser. For example, etching technology is generally used to remove a part or all of the formed film. However conventional etching technology is for removing unnecessary film by etching a flat surface, and even if a film with certain bumps is etched, the size of the bumps cannot be decreased since the etching rate of the film is constant, and the surface bumps cannot be controlled by etching to a sufficient degree for the light emitting surface. It is possible to completely remove a film with bumps and expose a flat under layer by etching stop. However in the case of the semiconductor device of the present invention, flattening of the nitride semiconductor layer is necessary, and it is very difficult to expose a flat nitride semiconductor layer by etching stop according to the conventional manufacturing method. Such etching technology has not yet been established.

### SUMMARY OF THE INVENTION

An object of the manufacturing method of a nitride semiconductor device of the present invention is to manufacture a nitride semiconductor device which excels in device characteristics and can emit light uniformly.

The manufacturing method of a nitride semiconductor device to achieve the above object is a manufacturing method of a nitride semiconductor device comprising a step of forming a substrate region of a nitride semiconductor device on a base material substrate and separating the base material substrate by laser lift-off, further comprising a first step of sequentially forming on the base material substrate at least a first nitride semiconductor layer and a second nitride semiconductor layer that has a slower etching rate than the first nitride semiconductor layer, a second step of separating the base material substrate and the first nitride semiconductor layer by irradiating, from the base material substrate side, a laser having an energy greater than an energy band gap of the first nitride semiconductor layer, and a third step of removing the first nitride semiconductor layer by etching.

The manufacturing method is characterized in that the first nitride semiconductor layer comprises Al_{X}Ga_{1-X}N (0≦X<1) and the second nitride semiconductor layer comprises Al_{Y}Ga_{1-Y}N (0<Y≦1, X<Y).

The manufacturing method is also characterized in that Y−X≧0.1 is established in the Al_{X}Ga_{1-X}N layer and the Al_{Y}Ga_{1-Y}N layer.

The manufacturing method is also characterized in that the etching removal in the third step is performed by dry etching using a mixed gas of at least chlorine gas and oxygen.

The manufacturing method is also characterized in that the etching removal in the third step is performed by wet etching.

The manufacturing method is also characterized in that the etching removal in the third step is performed on at least an area where light is guided, and electrodes are formed on the remaining area of the second nitride semiconductor layer.

The manufacturing method is also characterized in that a metal layer is formed on the nitride semiconductor layer before the second step.

The manufacturing method is also characterized in that Au, Ag or Cu is used for the metal layer.

The manufacturing method is also characterized in that the film thickness of the metal layer is not less than 10 μm.

The manufacturing method is also characterized in that the semiconductor substrate is bonded on the nitride semiconductor layer before the second step.

The manufacturing method is also characterized in that the semiconductor substrate has cleavability.

### BRIEF DESCRIPTION OF THE DRAWINGS

FIG. 1 is cross-sectional views schematically depicting steps of a manufacturing method of a nitride semiconductor device according to the present invention;

FIG. 2 is cross-sectional views depicting steps of a manufacturing method of a blue surface emitting laser according to Embodiment 1 of the present invention;

FIG. 3 is cross-sectional views depicting steps of a manufacturing method in which an n-GaN layer of a blue surface emitting laser is partially removed according to Embodiment 1 of the present invention;

FIG. 4 is cross-sectional views depicting steps of a manufacturing method of a blue LED according to Embodiment 2 of the present invention;

FIG. 5 is cross-sectional views depicting steps of a manufacturing method of an ultraviolet LED according to Embodiment 3 of the present invention; and

FIG. 6 is cross-sectional views depicting steps of a conventional manufacturing method of a Group III nitride semiconductor device using LLO.

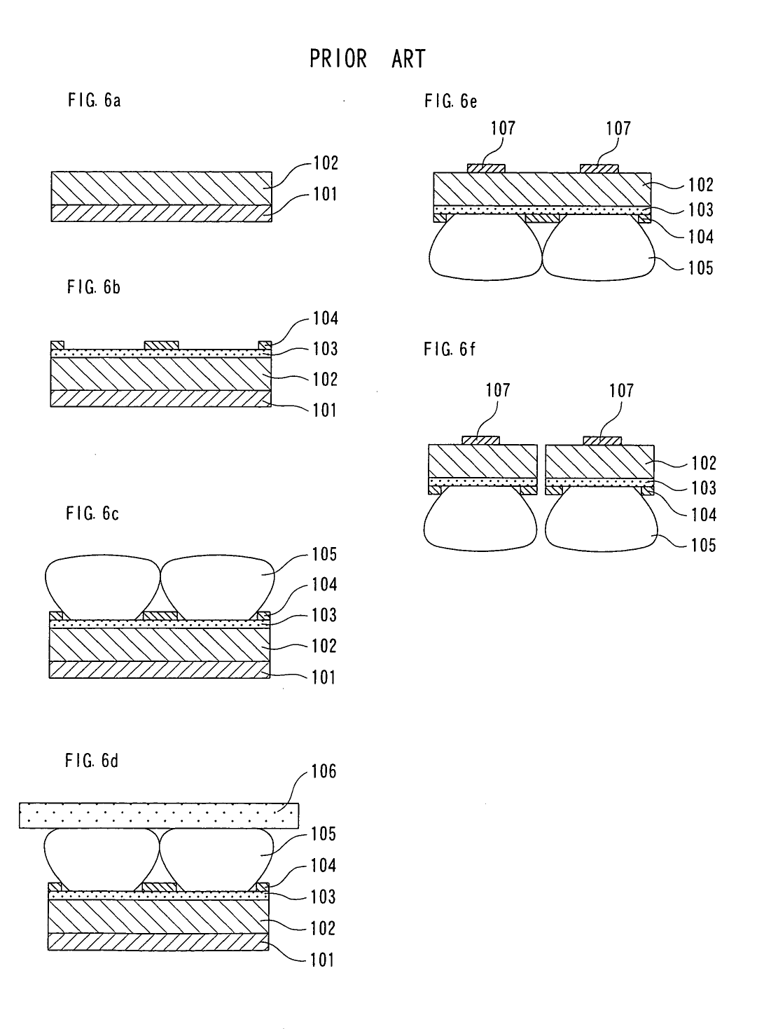

### DESCRIPTION OF THE PREFERRED EMBODIMENTS

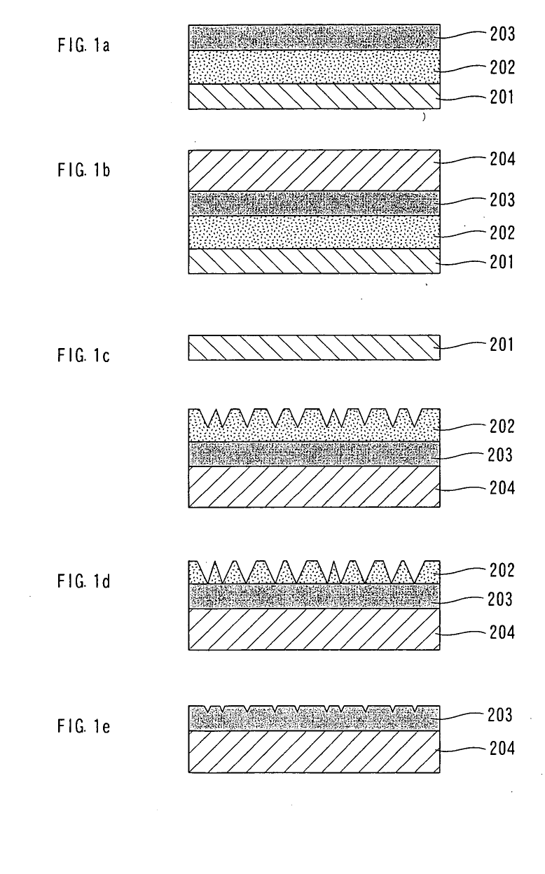

An overview of the present invention will be described with reference to FIG. 1.

FIG. 1 is cross-sectional views of steps depicting an overview of a manufacturing method of a nitride semiconductor device according to the present invention.

In FIG. 1, first the nitride semiconductor layer 202 and the nitride semiconductor layer 203 are sequentially formed on the base material substrate 201 (FIG. 1(a)). At this time, the nitride semiconductor layer 203 is formed with a material of which the etching rate is slower than the nitride semiconductor layer 202.

Then the holding material 204 is formed on the nitride semiconductor layer 203 (FIG. 1(b)). This holding material is formed to prevent cracking of the nitride semiconductor layers 202 and 203, which are thin films, when the base material substrate 201 and the nitride semiconductor layer 202 are separated in the next step.

After the holding material 204 is formed, a laser is irradiated from the base material substrate 201 side. For the laser, the wavelength that transmits the base material substrate 201 and is absorbed by the nitride semiconductor layer 202 is used, and the energy of the laser is greater than the energy band gap of the nitride semiconductor layer 202. By irradiating a laser having such a wavelength, the laser light is absorbed in the nitride semiconductor layer 202 at the area near the interface with the base material substrate 201, heat is generated, and a part of the nitride semiconductor layer 202 melts. As a result, the nitride semiconductor layer 202 and the base material substrate 201 are separated, and the surface of the nitride semiconductor layer 202, which is exposed after the separation, has bumps too large for the light emitting surface, (FIG. 1(c)). The top and bottom of the drawings are reversed between FIG. 1 (b) and FIG. 1(c).

If large bumps exist, various problems occur, and resist may not be able to be coated uniformly during the process. From the device point of view, the irregular reflection of light occurs on the rough bumpy surface, so if such a device as a surface emitting laser is fabricated, a major light absorption loss occurs and characteristics deteriorate.

So the nitride semiconductor layer 202 is etched next. AT this time, the etching rate is slower in the nitride semiconductor layer 203 than in the nitride semiconductor layer 202, as mentioned above. As the etching progresses, the nitride semiconductor layer 202 is completely removed at the concave areas of the nitride semiconductor layer 202 (FIG. 1(d)). As etching continues, etching progresses at the same rate in the portions where the nitride semiconductor layer 202 remains, and etching starts in the nitride semiconductor 203 in areas where the nitride semiconductor layer 202 is removed. Since the etching rate is faster in the nitride semiconductor layer 202 than the nitride semiconductor layer 203, etching progresses, gradually decreasing the size of the bumps. And when the nitride semiconductor layer 202 is completely removed, bumps are decreased to A/a (nm), where the size of the original bumps is A (nm) and the selection ratio (etching rate of the nitride semiconductor layer 202/etching rate of the nitride semiconductor layer 203) is=a (FIG. 1(e)).

Now an embodiment of the present invention will be described in detail with reference to the drawings.

### Embodiment 1

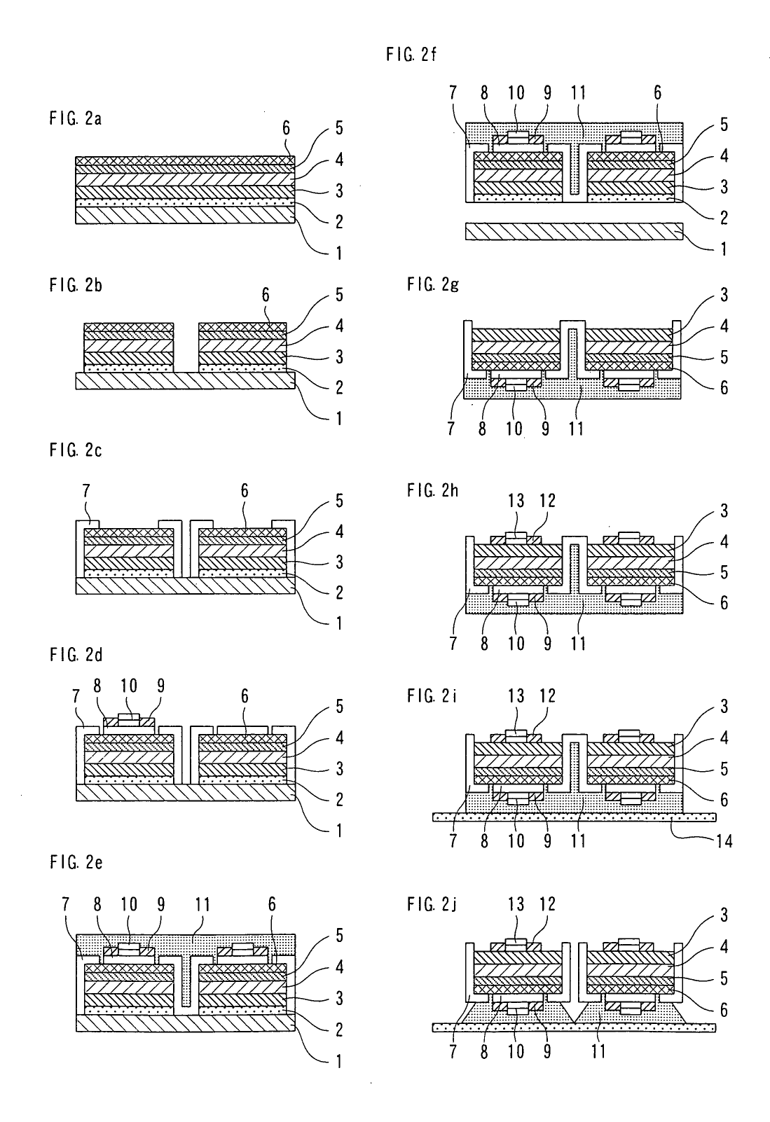

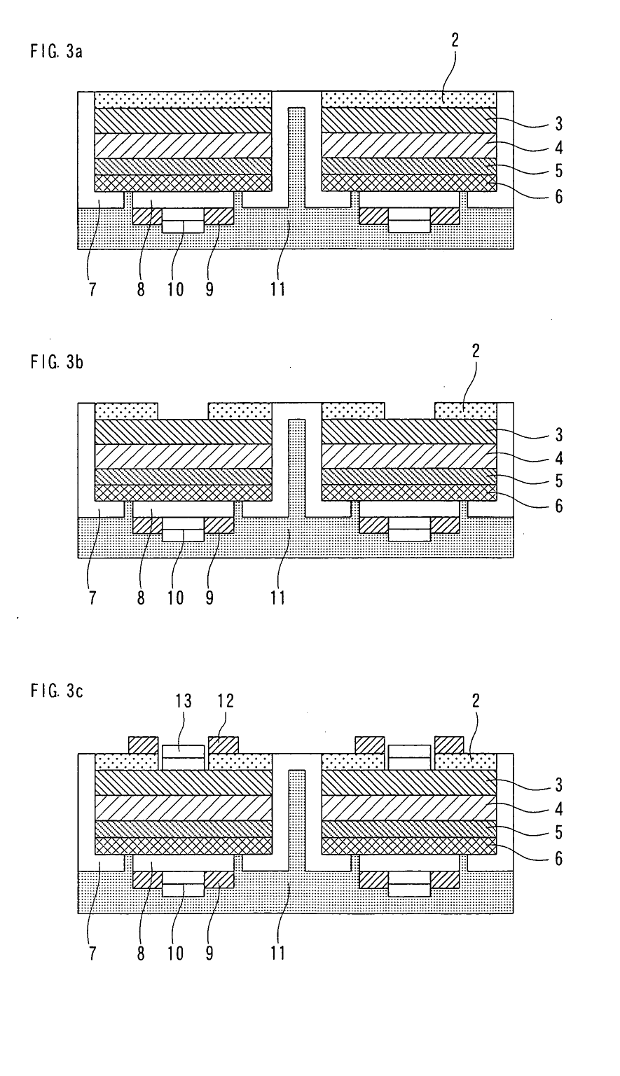

A manufacturing method of a blue surface emitting laser comprised of the nitride semiconductor according to Embodiment 1 of the present invention will be described with reference to FIG. 2 and FIG. 3.

FIG. 2 is cross-sectional views of steps depicting the manufacturing method of the blue surface emitting laser according to Embodiment 1, and FIG. 3 is cross-sectional views of steps depicting the manufacturing method of partially removing the n-GaN layer of the blue surface emitting laser according to Embodiment 1.

In FIG. 2, a MOVPE system, for example, is used for the system to grow a GaN layer. Trimethylgallium is used for the Ga material, trimethyl aluminum is used for the Al material, and NH₃ is used for the N material. SiH₄ is used for the material of Si, which is a donor impurity, and H₂ is used for the carrier gas. For the material of Mg, which is an acceptor impurity, cyclopentadienylmagnesium is used.

First on the 2 inch (0001) sapphire substrate 1, a low temperature buffer layer is formed, and then an n-GaN layer 2, n-Al_{0.15}Ga_{0.85}N clad layer 3, n-Al_{0.07}Ga_{0.93} guide layer 4, InGaN MQW active layer 5, p-Al_{0.07}Ga_{0.93}N guide layer, p-Al_{0.15}Ga_{0.85}N clad layer, and p-GaN contact layer are sequentially formed. In FIG. 2, the low temperature buffer layer is omitted, and the p-Al_{0.07}Ga_{0.93}N guide layer, p-Al_{0.15}Ga_{0.85}N clad layer and p-GaN contact layer are collectively shown as the p-type layer 6. From the InGaN MQW active layer 5 formed in this embodiment, a blue light emission with a wavelength of about 405 nm is generated (FIG. 2(a)).

After depositing these films, annealing is performed for 20 minutes at 760° C. in a nitrogen atmosphere, so as to further decrease the resistance of the p type layer 6.

After annealing, the GaN layer at the chip separation portion is completely removed by etching (FIG. 2(b)). For this etching, dry etching, such as RIE and ECR, is appropriate. For the etching gas, chlorine gas is preferable.

After dry etching, SiO₂ film 7 is formed on the entire surface, and the SiO₂ film 7s is partially removed by BHF (FIG. 2(c)). At portions where the SiO₂ film 7 is removed, ITO (Indium Tin Oxide) 8 is formed as a transparent electrode, then an Ni/Au electrode is formed as a p type electrode 9 in a portion other than the optical wave guide area. After forming the p-type electrode 9, annealing is performed at 500° C. in an oxygen atmosphere.

After annealing, the dielectric DBR mirror 10 is formed at the optical wave guide area of the portion where ITO 8 is formed. The dielectric DBR mirror 10 is configured such that the reflectance of the light with a wavelength of 405 nm is 99% or more (FIG. 2(d)).

After forming the dielectric DBR mirror 10, Ti/Au is formed as an Au plating substrate, and Au plating 11 is formed on the Au plating substrate sequentially using an EB deposition device. The Au plating 11 functions as the holding material of the GaN growth layer, which becomes a thin film after LLO, so the thickness thereof is preferably 10 μm or more (FIG. 2(e)). In the present embodiment, the thickness of the Au plating 11 is 50 μm. Metal materials preferably excel in heat radiation, and Cu or Ag may be used instead of Au. In the present embodiment, such a thick film metal layer as Au plating 11 is used as the holding material, but the semiconductor substrate may be bonded onto the GaN growth layer to function as the holding material. At this time, the chip separation step becomes easier if a semiconductor substrate with cleavage is used.

After forming the Au plating 11, a laser is irradiated from the sapphire substrate 1 side to separate the sapphire substrate 1 at the rear face (FIG. 2(f)). After LLO, the separated Ga metals, which attached in the area near the interface, are removed by hydrochloric acid. During this time, the GaN layer absorbs the laser light, and the GaN layer melts by the heat generated at this time according to LLO technology, and the non-uniform heat generates bumps of about 20 nm on the n-GaN layer 2.

After removing the sapphire substrate 1, the n-GaN layer 2 is completely removed by dry etching (FIG. 2(g)). The top and bottom of the drawing are reversed between FIG. 2(f) and FIG. 2(g). For the dry etching device, ECR, ICP and RIE are permissible. For the etching gas, a gas mixture of oxygen, chlorine and argon is used. Normally only chlorine gas or a gas mixture of chlorine and argon is used for the etching gas, but a mixture of oxygen gas thereto makes it possible to increase the selection ratio of the etching rate of the n-GaN layer 2 and the n-Al_{0.15}Ga_{0.85}N clad layer 3. If the selection ratio of the etching rate (hereafter called selection ratio of etching, or simply selection ratio) is assumed to be n-GaN layer 2/n-Al_{0.15}Ga_{0.85}N clad layer 3=a, the bumps can be decreased to 20/a (nm) by removing the n-GaN layer 2 completely. In the present embodiment, the layer to be removed by etching is the n-GaN layer 2 (0% Al composition), but if an AlGaN layer, of which the Al composition is smaller than the n-Al_{0.15}Ga_{0.85}N clad layer 3, is used instead of the n-GaN layer 2, the selection ratio of etching becomes 1 or more, which is effective.

To decrease light loss, it is preferable that the bumps of the Al_{Y}Ga_{1-Y} layer is 1 nm or less. For this, the selection ratio of the Al_{X}Ga_{1-X}N layer and the Al_{Y}Ga_{1-Y}N layer must be 20 or more. By experiment, it is effective, in order to obtain a selection ratio of 20 or more, if the difference of the Al composition of the Al_{X}Ga_{1-X}N layer and the Al_{Y}Ga_{1-Y}N layer is set to be 10% or more.

If the structure of the n-GaN layer 2 and the n-Al_{0.15}Ga_{0.85}N clad layer 3 is used, the n-GaN layer 2 can be removed by wet etching, with which flattening is normally difficult. For example, the n-GaN layer 2 can be removed by soaking the wafer in KOH etchant, and irradiating UV on the wafer. The difference of the etching rate between the n-GaN layer 2 and the n-Al_{0.15}Ga_{0.85}N clad layer 3 is large, and in an experiment, it was confirmed that the etching amount of the n-Al_{0.15}Ga_{0.85}N is extremely small compared with the etching amount of n-GaN. In other words, the selection ratio of the etching rate n-GaN layer 2/n Al_{0.15}Ga_{0.85}N clad layer 3 is very large, so as a result the n-Al_{0.15}Ga_{0.85}N clad layer 3 can be flattened very easily. Wet etching has an advantage over dry etching in that damage to the sample is minimal.

Then Ti/Au is formed in a portion other than the optical wave guide area by EB deposition as the n-type electrode 12, and sintering is executed at 500° C. in a nitrogen atmosphere. After sintering, the dielectric DBR mirror 13 is formed at the optical wave guide area (FIG. 2(h)). The dielectric DBR mirror 13 is constructed such that the reflectance of the light with a wavelength of 405 nm becomes 99% or more. In the present embodiment, the dielectric material is used for the DBR mirror at the n-type layer side, but the DBR mirror may be formed by a growth layer using the reflective index difference of the AlGaN with a different composition.

After forming the dielectric DBR mirror 13, a sheet 14 having adhesion is bonded at the Au plating 11 side (FIG. 2(i)).

Then the SiO₂ film 7 at the device separation area and Ti at the Au plating substrate are removed by BHF. Then using iodine, the Au plating 11 is etched and chips are separated, and as a result, the blue color surface emitting lasers can be fabricated (FIG. 2(j)).

The effect of such a configuration will be described below.

When LLO is performed on the semiconductor device, where the Al_{Y}Ga_{1-Y}N layer, Al_{X}Ga_{l-X}N layer and sapphire layer are formed in this sequence, the Al_{X}Ga_{1-X}N layer (0≦X<1) absorbs light, and thermal decomposition occurs. At this time, large bumps, which affect the device characteristics, are formed on the Al_{X}Ga_{1-X}N layer by the non-uniformity of the heat generated. Therefore the Al_{X}Ga_{1-X}N layer is completely removed by dry etching. A dry etching condition in this case is that the etching rate of the Al_{Y}Ga_{1-Y}N layer is much slower than that of the Al_{X}Ga_{1-X}N layer. If the size of the bumps formed on the Al_{X}Ga_{1-X}N layer is A (nm), and the selection ratio of the etching rate of the Al_{X}Ga_{1-X}N layer/etching rate of the Al_{Y}Ga_{1-Y}N layer is=a, then the size of the bumps formed on the Al_{Y}Ga_{1-Y}N layer after the Al_{X}Ga_{1-X}N layer is completed removed becomes A/a (nm), which is much less compared with the time immediately after LLO. By etching the two layers having different etching rates in this way, the bumps formed on the Al_{Y}Ga_{1-Y}N layer can be controlled at an appropriate accuracy for a plane used for the laser, and as a result, the characteristics of the nitride semiconductor device fabricated using LLO technology can be dramatically improved.

The surface emitting laser fabricated as above excels in flatness of the interface after LLO, so the scattering loss of light at the interface is less, and excellent characteristics can be implemented.

FIG. 3 shows a variant form of Embodiment 1.

In FIG. 3 the steps up to removing the sapphire substrate 1 by LLO technology is the same as Embodiment 1 (FIG. 3(a)).

Then just like Embodiment 1, the n-GaN layer 2 is removed, but in this case, dry etching is partially performed, as opposed to on the entire surface (FIG. 3(b)). Here the portion where light is guided must be dry etched.

Then the n-type electrode 12 is formed in the portion where dry etching was not performed (FIG. 3(c)). The portion where dry etching was not performed is a layer where the Al composition is low, compared with the portion exposed by dry etching. Therefore a low contact resistance can be easily implemented when the n-type electrode 12 is formed, which improves the device characteristics. The steps after the n-type electrode 12 is formed are the same as Embodiment 1.

By this configuration, the electrode can be formed on the low Al composition area where dry etching was not performed, so a low contact resistance can be easily implemented and the device characteristics can be improved.

### Embodiment 2

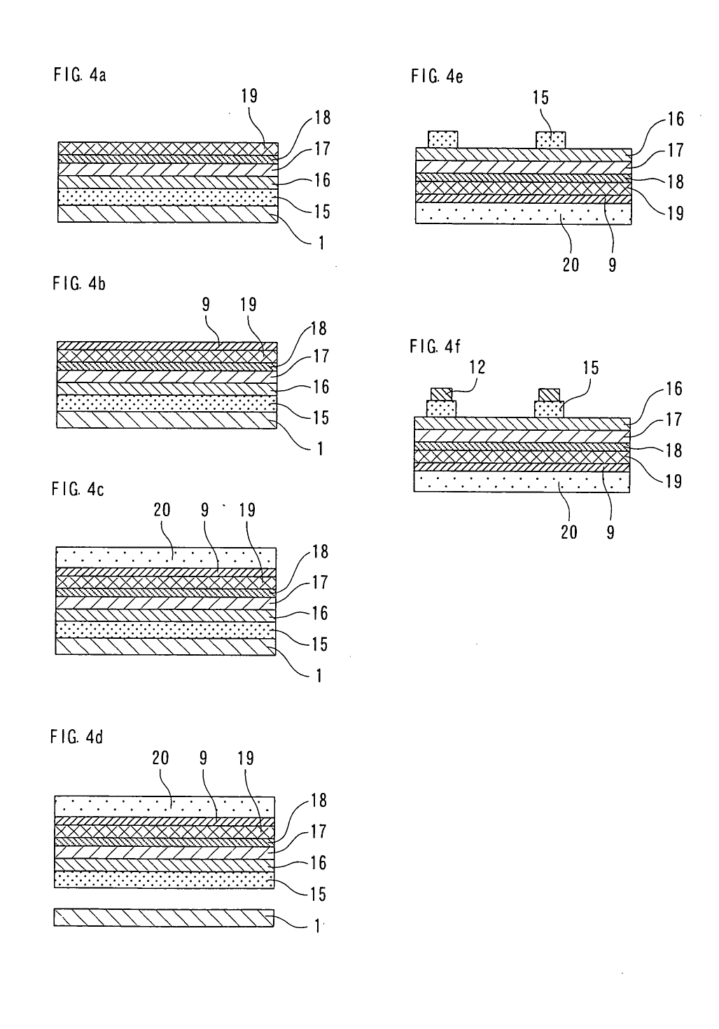

A manufacturing method of a blue LED comprised of a nitride semiconductor according to Embodiment 2 will be described with reference to FIG. 4.

FIG. 4 is cross-sectional views of steps depicting the manufacturing method of the blue surface emitting device according to Embodiment 2.

For the GaN layer growth system, a MOVPE (Metal Organic Vapor Phase Epitaxial growth) system is used. First a low temperature buffer layer is formed in the 2 inch (0001) sapphire substrate 1, then the n-GaN 15 is grown 1 μm, n-Al_{0.1}Ga_{0.9}N 16 is grown 0.5 μm, and n-GaN 17 is grown 3 μm. Then the carrier gas is switched to N₂, and an InGaN active layer 18 is grown to be a 20 nm film thickness. From the InGaN active layer 18 formed in the present embodiment, a blue light emission with a 470 nm wavelength is generated. For the material of In, trimethylindium is used. In the present embodiment, the active layer has an SQW structure, but this may be an MQW structure. Then finally the p-GaN 19 is grown 0.8 μm. For the material of Mg, which is an acceptor impurity, cyclopentadienylmagnesium is used (FIG. 4(a)).

After growing the p-GaN 19, annealing is performed for 20 minutes at 750° C. in a nitrogen atmosphere using an annealing device, so as to further decrease the resistance of p-GaN 19 at the top layer. After annealing, Ni/Pt/Au is deposited on p-GaN 19 as the p-type electrode 9 using EB deposition (FIG. 4(b)), then sintering is performed at 600° C. in a nitrogen atmosphere.

After forming the p-type electrode 9, the GaAs substrate 20 is bonded onto the p-type electrode 9 (FIG. 4(c)). The GaAs substrate 20 functions as the holding material for the GaN layer, which becomes a thin film after the sapphire substrate is removed by LLO. Here the function of the GaAs substrate is the same as the Au plating in Embodiment 1. The substrate to be bonded may be an SiC substrate, Si substrate or an AlN substrate, for example, instead of the GaAs substrate.

Then the laser is irradiated from the sapphire substrate 1 side to separate the sapphire substrate 1 (FIG. 4(d)). At this time, bumps of about 20 nm are formed on the n-GaN 15 for the same reason as Embodiment 1.

If the surface roughness is even within the surface, the light emission efficiency may be improved in some cases, but roughness is uneven within the surface, and portions where the emission is strong and emission is weak coexist, which makes the device characteristics unstable.

After the sapphire substrate 1 is separated, dry etching is performed on the n-GaN 15 only in the light emitting portion (FIG. 4(e)). The top and bottom of the drawings are reversed between FIGS. 4(d) and (e). A dry etching condition to be used is that the etching rate difference of the n-GaN 15 and the n-Al_{0.1}Ga_{0.9}N 16 is large. If the etching rate of n-GaN 15/etching rate of n-Al_{0.1}Ga_{0.9}N 16 is=a, then the size of the bumps can be decreased to 20/a (nm) in the status when n-GaN 15 is completed removed and n-Al_{0.1}Ga_{0.9}N 16 is exposed.

After dry etching, the n-type electrode 12 is formed in a portion other than the light emitting area, where dry etching was not performed (FIG. 4(f)). For the electrode material, Ti/Al/Ni/Au is used, and the electrode is formed by EB deposition. Then sintering is performed for 15 minutes at 500° C. in a nitrogen atmosphere.

After sintering of the N electrode is performed, the GaAs substrate 20 is polished and cleaved, and as a result the blue LEDs are fabricated.

In this way, by performing LLO for a semiconductor device where the Al_{Y}Ga_{1-Y}N layer, the Al_{X}Ga_{1-X}N layer of which the etching rate is much faster than the Al_{Y}Ga_{1-Y}N layer, and a sapphire substrate are formed in this sequence, and the Al_{X}Ga_{1-X}N layer is completely removed by dry etching according to the manufacturing method of a blue LED, the bumps formed on the Al_{Y}Ga_{1-Y}N layer can be controlled with appropriate accuracy for the laser light emitting surface, and since the light emitting surface is very flat, light can be uniformly emitted.

### Embodiment 3

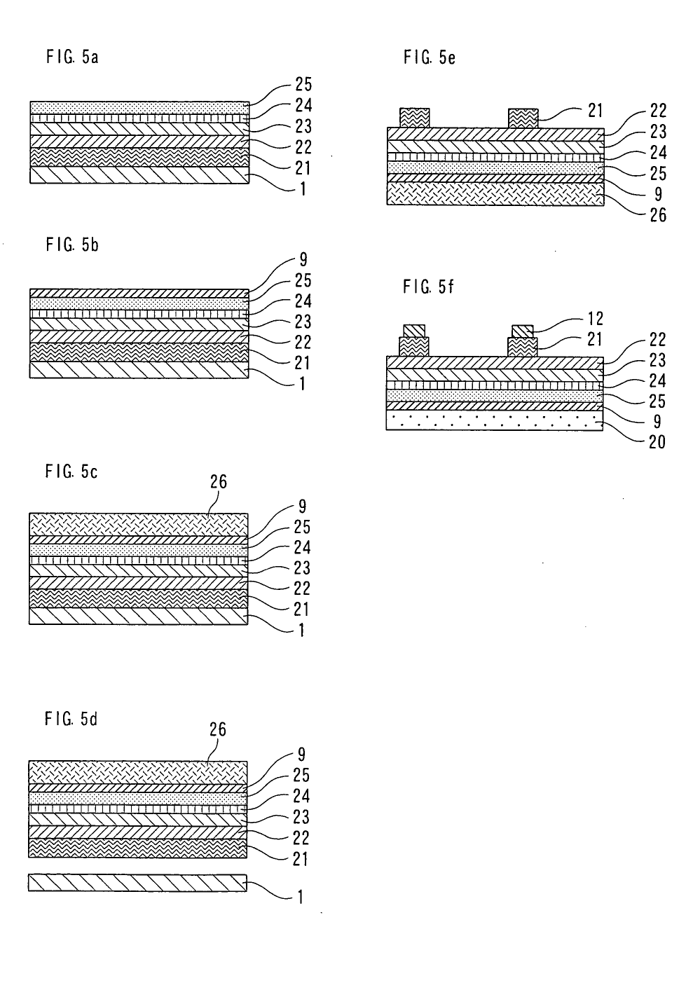

A manufacturing method of an ultraviolet LED comprised of the nitride semiconductor according to Embodiment 3 will be described with reference to FIG. 5.

FIG. 5 is cross-sectional views of steps depicting the manufacturing method of the ultraviolet LED according to Embodiment 3.

For the GaN layer growth system, a MOVPE (Metal Organic Vapor Phase Epitaxial growth) system is used.

In FIG. 5, the low temperature buffer layer is formed on the 2 inch (0001) sapphire substrate 1 first, then the n-GaN 21 is grown 0.3 μm, and the n-Al_{0.15}Ga_{0.85}N 22 is grown 0.7 μm. Then the carrier gas is switched to N₂, and the active layer 23, comprised of a barrier layer which is an AlGaN layer and well layer which is an InAlGaN layer, is grown. From the InAlGaN active layer 23 formed in the present embodiment, ultraviolet emission with a 360 nm wavelength is generated. For the material of In, trimethy indium is used. In the present embodiment, the active layer has an SQW structure, but may have an MQW structure. Then the p-AlGaN 24 is grown 0.1 μm and the p-GaN contact layer 25 is grown 0.02 μm (see FIG. 5(a)).

After growing the p-GaN contact layer 25, annealing is performed for 20 minutes at 750° C. in a nitrogen atmosphere using an annealing device, so as to further decrease the resistance of the p-GaN contact layer 25 at the top layer. After annealing, Ni/Pt/Au is deposited on the p-GaN contact layer 25 as the p-type electrode 9, using EB deposition (FIG. 5(b)), then sintering is performed at 600° C. in a nitrogen atmosphere.

After forming the p-type electrode 9, the Si substrate 26 is bonded onto the p-type electrode 9 (FIG. 5(c)). The Si substrate 26 functions as the holding material for the GaN layer which becomes a thin layer after the sapphire substrate is removed by LLO. The substrate may be a GaAs substrate, SiC substrate or AlN substrate, for example, instead of an Si substrate, as mentioned in Embodiment 2. Here the function of the Si substrate is the same as the Au plating in Embodiment 1.

Then the laser is irradiated from the sapphire substrate 1 side to separate the sapphire substrate (FIG. 5(d)). At this time, bumps of about 20 nm are formed on the n-GaN 21 for the same reason as Embodiment 1.

After the sapphire substrate 1 is separated, dry etching is performed on the n-GaN 21 only in the light emitting portion (FIG. 5(e)). The top and bottom of the drawings are reversed between FIGS. 5(d) and (e). A dry etching condition to be used is that the etching rate difference of the n-GaN 21 and n-Al_{0.15}Ga_{0.85}N 22 is large. If the etching rate of n-GaN 21 and the etching rate of n-Al_{0.15}Ga_{0.85}N 22 is=a, then the size of the bumps can be decreased to 20/a (nm) in the status when the n-GaN is completely removed and the n-Al_{0.15}Ga_{0.85}N 22 is exposed.

Not only the size of the bumps decreases but also the following effect is implemented in the present embodiment. The wavelength from the active layer according to the present embodiment is 360 nm, so if the n-GaN 21 remains, light is absorbed by this layer. But according to the present embodiment, the n-GaN 21 at the light emitting area is removed, so light absorption can be eliminated and the light output improves. In this way, in the case of an ultraviolet LED, a significant effect can be implemented by this configuration.

After dry etching, the n-type electrode 12 is formed in a portion other than the light emitting area, where dry etching was not performed (FIG. 5(f)). For the electrode material, Ti/Al/Ni/Au is used, and the electrode is formed by EB deposition. Then sintering is performed for 15 minutes at 500° C. in a nitrogen atmosphere.

After the sintering of the N electrode is performed, the Si substrate 26 is polished and cleaved, and as a result, the ultraviolet LEDs are fabricated.

In this way, by performing LLO for a semiconductor device where the Al_{Y}Ga_{1-Y}N layer, Al_{X}Ga_{1-X}N layer of which the etching rate is faster than the Al_{Y}Ga_{1-Y}N layer, and a sapphire substrate are formed in this sequence, and by completely removing the Al_{X}Ga_{1-X}N layer by dry etching according to the manufacturing method of the ultraviolet LED, the bumps formed on the Al_{Y}Ga_{1-Y}N layer can be controlled with an appropriate accuracy for the laser light emitting surface, and since the light emitting surface is very flat, light can be uniformly emitted.

1. A manufacturing method of a nitride semiconductor device comprising a step of forming a substrate region of a nitride semiconductor device on a base material substrate and separating the base material substrate by laser lift-off, the method further comprising:
a first step of sequentially forming on said base material substrate at least a first nitride semiconductor layer and a second nitride semiconductor layer having a slower etching rate than said first nitride semiconductor layer;
a second step of separating said base material substrate and said first nitride semiconductor layer by irradiating a laser from the base material substrate side, the laser having an energy greater than an energy band gap of said first nitride semiconductor layer; and
a third step of removing said first nitride semiconductor layer by etching.

2. The manufacturing method of a nitride semiconductor device according to claim 1, wherein said first nitride semiconductor layer comprises Al_{X}Ga_{1-X}N (0≦X<1) and said second nitride semiconductor layer comprises Al_{Y}Ga_{1-Y}N (0<Y≦1, X<Y).

3. The manufacturing method of a nitride semiconductor device according to claim 2, wherein Y−X≧0.1 is established in said Al_{X}Ga_{1-X}N layer and said Al_{Y}Ga_{1-Y}N layer.

4. The manufacturing method of a nitride semiconductor device according claim 1, wherein the etching removal in said third step is performed by dry etching using a mixed gas of at least chlorine-based gas and oxygen.

5. The manufacturing method of a nitride semiconductor device according to claim 1, wherein the etching removal in said third step is performed by wet etching.

6. The manufacturing method of a nitride semiconductor device according to claim 4, wherein the etching removal in said third step is performed on at least an area where light is guided, and electrodes are formed on the remaining area of said second nitride semiconductor layer.

7. The manufacturing method of a nitride semiconductor device according to claim 4, wherein a metal layer is formed on said nitride semiconductor layer before said second step.

8. The manufacturing method of a nitride semiconductor device according to claim 7, wherein Au, Ag or Cu is used for said metal layer.

9. The manufacturing method of a nitride semiconductor device according to claim 7, wherein the film thickness of said metal layer is not less than 10 μm.

10. The manufacturing method of a nitride semiconductor device according to claim 4, wherein a semiconductor substrate is bonded onto said nitride semiconductor layer before said second step.

11. The manufacturing method of a nitride semiconductor device according to claim 10, wherein said semiconductor substrate has cleavability.
